(19) United States
(12) Patent Application Publication
(10) Pub. No.: US 2025/0044317 A1
(43) Pub. Date: Feb. 6, 2025

(54) Circuit Device And Physical Quantity Sensor

(71) Applicant: SEIKO EPSON CORPORATION, Tokyo (JP)

(72) Inventors: Kaoru ICHINOSE, Matsumoto (JP); Hideo HANEDA, Shiojiri (JP); Tomoaki TAKAHASHI, Minowa (JP)

(21) Appl. No.: 18/792,917

(22) Filed: Aug. 2, 2024

(30) Foreign Application Priority Data
Aug. 4, 2023 (JP) 2023-127610

(51) Int. Cl. G01P 3/44

(52) U.S. Cl. CPC G01P 3/44

(57) ABSTRACT

A circuit device is constituted by including: a detection circuit configured to include a first A/D conversion circuit that A/D converts a signal output from a sensor element to output a first digital signal and generate a detection signal in accordance with the first digital signal; a pseudo-detection circuit configured to include a second A/D conversion circuit that A/D converts a signal output from the sensor element to output a second digital signal and generate a pseudo-detection signal in accordance with the second digital signal; and a failure detection circuit configured to detect a failure of the detection circuit in accordance with a comparison result produced by comparing a value of the detection signal and a value of the pseudo-detection signal.

The present application is based on, and claims priority from JP Application Serial Number 2023-127610, filed Aug. 4, 2023, the disclosure of which is hereby incorporated by reference herein in its entirety.

### BACKGROUND

### 1. Technical Field

The present disclosure relates to a circuit device and a physical quantity sensor.

### 2. Related Art

The configuration of a device for detecting a failure of a circuit device is known. For example, JP-A-2016-170136 discloses the configuration in which diagnosis processing is performed before a normal operation period after the power is turned on. By the diagnosis processing, a diagnosis signal is input to a detection circuit that detects the output signal of a physical quantity transducer. A diagnosis is made as to whether or not the detection circuit is operating normally in accordance with a response to the diagnosis signal.

A failure might occur at the time of using a detection circuit. Accordingly, it is desired to enable failure detection not only before a normal operation period, but also during use of the detection circuit.

### SUMMARY

According to an aspect of the present disclosure, there is provided a circuit device including: a detection circuit configured to include a first A/D conversion circuit that A/D converts a signal output from a sensor element to output a first digital signal and generate a detection signal in accordance with the first digital signal; a pseudo-detection circuit configured to include a second A/D conversion circuit that A/D converts a signal output from the sensor element to output a second digital signal and generate a pseudo-detection signal in accordance with the second digital signal; and a failure detection circuit configured to detect a failure of the detection circuit in accordance with a comparison result produced by comparing a value of the detection signal and a value of the pseudo-detection signal.

According to another aspect of the present disclosure, there is provided a physical quantity sensor including: a sensor element; a detection circuit configured to include a first A/D conversion circuit that A/D converts a signal output from the sensor element to output a first digital signal and generate a detection signal in accordance with the first digital signal; a pseudo-detection circuit configured to include a second A/D conversion circuit that A/D converts a signal output from the sensor element to output a second digital signal and generate a pseudo-detection signal in accordance with the second digital signal; and a failure detection circuit configured to detect a failure of the detection circuit in accordance with a comparison result produced by comparing a value of the detection signal and a value of the pseudo-detection signal.

### BRIEF DESCRIPTION OF THE DRAWINGS

FIG. 1 is a block diagram of a physical quantity sensor including a circuit device according to a first embodiment.

FIG. 2 is a diagram illustrating an example of the configuration of a drive circuit.

FIG. 3 is a diagram illustrating an example of the configuration of a detection circuit and a pseudo-detection circuit.

FIG. 4 is a diagram illustrating an input/output example of a clip processing section.

FIG. 5 is a diagram illustrating an input/output example of a clip processing section.

FIG. 6 is a diagram illustrating an example of the configuration of a failure detection circuit.

FIG. 7 is a diagram illustrating an example of the configuration of a value determination section.

FIG. 8 is a diagram illustrating an example of the configuration of a rate of change determination section.

FIG. 9 is a diagram illustrating a sine wave.

### DESCRIPTION OF EMBODIMENTS

### 1. First Embodiment

In the following, a detailed description will be given of preferred embodiments of the present disclosure with reference to the drawings. In this regard, the embodiments described below do not unreasonably restrict the contents described in the scope of the claims. Note that not all the components of the configurations described below are necessarily mandatory constituent features. Hereinafter a description will be given of the embodiments by taking a sensor element that detects angular velocity, that is, an angular velocity sensor, as an example.

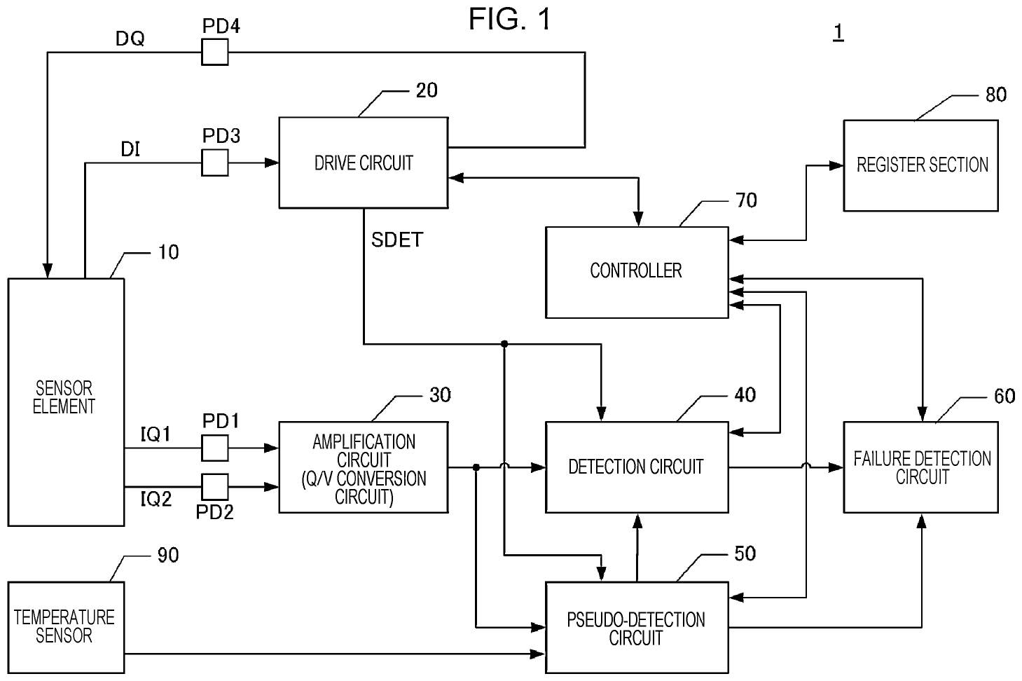

FIG. 1 is a block diagram illustrating an example of the configuration of a physical quantity sensor 1 including a circuit device according to the present embodiment. The physical quantity sensor 1 illustrated in FIG. 1 includes a sensor element 10, a drive circuit 20, an amplification circuit 30, a detection circuit 40, a pseudo-detection circuit 50, a failure detection circuit 60, a controller 70, a register section 80, and a temperature sensor 90.

In the present embodiment, the sensor element 10 is an angular velocity sensor. It is possible to realize the angular velocity sensor by using various publicly known configurations. For example, it is possible to configure the sensor element 10 by using an element that outputs vibration based on a Coriolis force acting on the vibrating arm, or the like. Of course, the shape of the sensor is not limited, and it is possible to use a sensor with various shapes, such as a double T type, a tuning fork type, an H type, or the like.

The sensor element 10 includes an input terminal to which a drive signal DQ is input from the drive circuit 20 and an output terminal from which a feedback signal DI is output to the drive circuit 20. In the present embodiment, the input terminal is electrically coupled to a pad PD4. Also, the output terminal is electrically coupled to a pad PD3. The sensor element 10 includes two detection signal output terminals that output a detection signal. The respective detection signal output terminals are electrically coupled to pads PD1 and PD2.

The drive circuit 20 drives the sensor element 10. The drive circuit 20 is electrically coupled to the sensor element 10 via the pads PD3 and PD4. The drive circuit 20 drives the sensor element 10 by receiving a feedback signal DI from the sensor element 10 via the pad PD3, and outputting the drive signal DO corresponding to the feedback signal DI via the pad PD4.

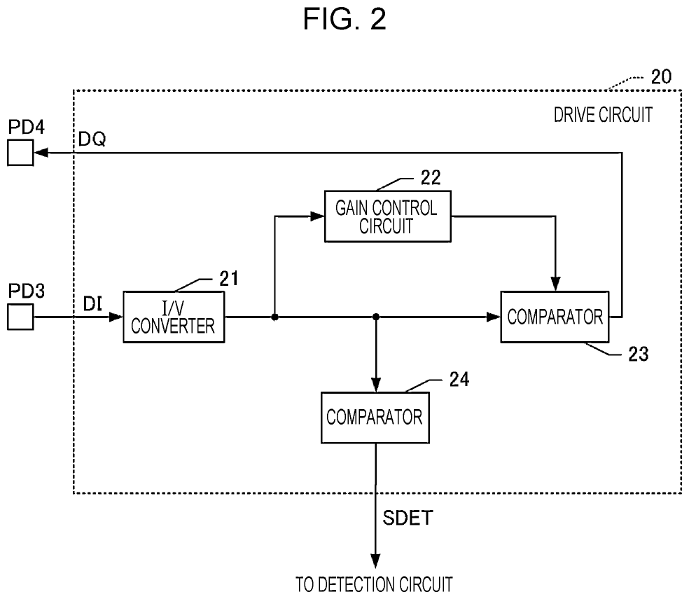

It is possible to realize the drive circuit 20 by using various publicly known circuits. FIG. 2 is an example of the configuration of the drive circuit 20. It is possible to realize the drive circuit 20 illustrated in FIG. 2 by using the configuration including a current voltage converter (I/V converter) 21, a gain control circuit 22, a comparator 23, and a comparator 24. These individual circuits are able to be realized by using a publicly known configuration.

In the example illustrated in FIG. 2, when the feedback signal DI is input from the sensor element 10 to the current voltage converter 21 via the pad PD3, the current voltage converter 21 converts the feedback signal DI to an AC voltage signal with the same frequency as the vibration frequency of the feedback signal DI and outputs the AC voltage signal.

The AC voltage signal output from the current voltage converter 21 is input to the comparator 23 and the comparator 24. The comparator 23 converts the AC voltage signal of the current voltage converter 21 to a square wave and inputs the square wave to the sensor element 10 as the drive signal DQ. As a result, the sensor element 10 is driven by the drive signal DQ. The gain control circuit 22 controls a reference voltage of the comparator 23 so as to hold the amplitude of the input AC voltage signal at a fixed value.

The comparator 24 compares the AC voltage signal and the reference voltage signal by using a center of the amplitude of the AC voltage signal output from the current voltage converter 21 as a reference voltage. The comparator 24 outputs a square wave voltage signal that changes its output level so as to become a high level when the former is higher and become a low level when the latter is higher. The square wave voltage signal is a signal generated in accordance with the drive signal DQ and is used for synchronous detection described later. Here, the square wave voltage signal is therefore referred to as a synchronous detection signal SDET. The synchronous detection signal SDET is input to the detection circuit 40 and the pseudo-detection circuit 50.

The sensor element driven by the drive circuit 20 outputs a first and a second detection signals IQ1 and IQ2 from the respective detection signal output terminals. The first and second detection signals IQ1 and IQ2 constitute a differential signal and are input to the amplification circuit 30 via the pads PD1 and PD2 respectively. The amplification circuit 30 is a Q/V conversion circuit and includes a Q/V conversion circuit to which the first detection signal IQ1 is input and a Q/V conversion circuit to which the second detection signal IQ2 is input. The Q/V conversion circuit (charge amplifier) is a circuit that converts a charge signal (minute charge signal, micro current signal) from the sensor element 10 to a voltage signal, and may be thought as a kind of an I/V conversion circuit.

The first and the second voltage signals produced by converting the first and the second detection signals IQ1 and IQ2, respectively, have reversed phases with respect to each other and constitute a differential signal. However, for simplicity, the output signals are illustrated by an arrow in FIG. 1. The first and the second voltage signals output from the amplification circuit 30 are input to the detection circuit 40 and the pseudo-detection circuit 50 respectively.

The detection circuit 40 is a circuit that outputs a detection signal indicating an angular velocity detected by the sensor element 10 in accordance with the first and the second voltage signals output from the amplification circuit 30. The detailed configuration of the detection circuit 40 will be described later.

The pseudo-detection circuit 50 includes a circuit that reproduces the operation of the detection circuit 40 in a pseudo-manner in accordance with the first and the second voltage signals output from the amplification circuit 30 and is a circuit that outputs a pseudo-detection signal imitating the detection signal. A detailed configuration of the pseudo-detection circuit 50 will be described later.

The failure detection circuit 60 is a circuit that detects a failure of the detection circuit in accordance with a comparison result produced by comparing a detection signal value output from the detection circuit 40 and a pseudo-detection signal value output from the pseudo-detection circuit 50. A detailed configuration of the failure detection circuit 60 will be described later.

The controller 70 performs various kinds of control processing. For example, the controller 70 performs the control processing of the detection circuit 40, the pseudo-detection circuit 50, and the failure detection circuit 60. It is possible to realize the controller 70, for example, by using a logic circuit such as a gate array or the like that is generated by an automatic placement and a routing method, or by a processor or the like operating in accordance with firmware or the like.

The register section 80 includes a register storing various kinds of information. It is possible to realize the register section 80, for example, by using memory such as an SRAM or the like, a flip-flop circuit, or the like. In the present embodiment, the various kinds of information stored in the register section 80 includes, a gain (det_gain, Vth_gain), an offset (det_offs, Vth_offs), a second threshold value del_Vth, a filter coefficient, and the like, which are described later. These kinds of information is obtained by the controller 70 and is supplied to each circuit.

The temperature sensor 90 is a sensor that outputs a voltage level signal (temperature signal) in accordance with the ambient temperature. The higher the temperature, the higher the positive polarity of the output voltage may be, or the higher the temperature, the lower the negative polarity of the output voltage may be. The temperature sensor 90 may be a circuit, for example, that outputs a voltage (PTAT (proportional to absolute temperature) voltage) proportional to the absolute temperature. The temperature signal output from the temperature sensor 90 is input to the pseudo-detection circuit 50.

### 1.1 Configuration of Detection Circuit

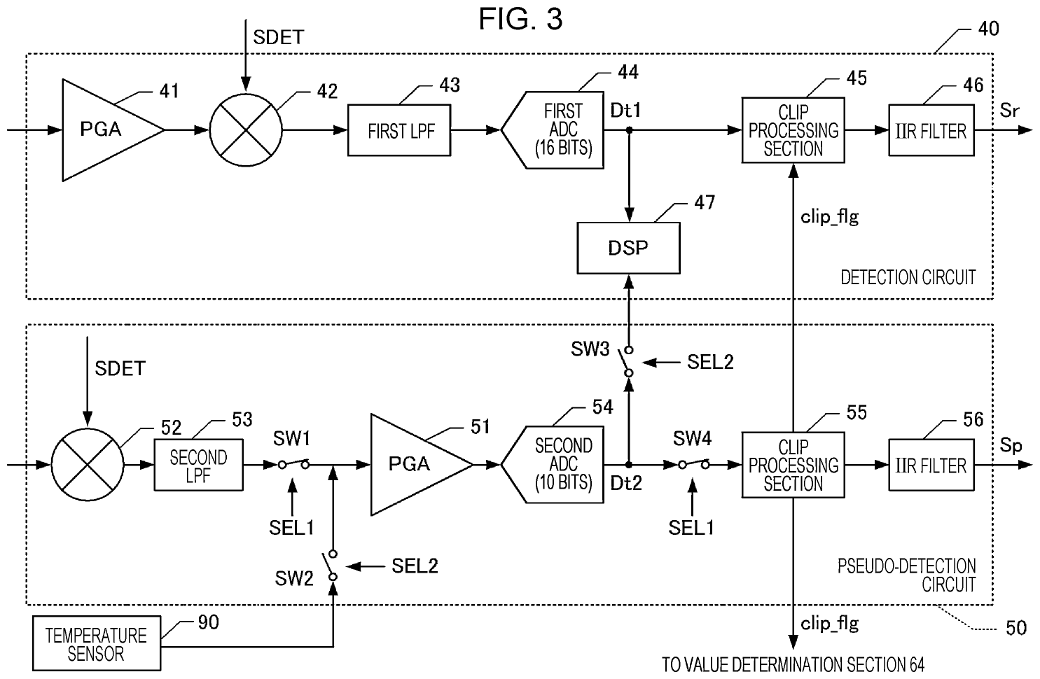

Next, a detailed description will be given of the configuration of the detection circuit 40. FIG. 3 illustrates an example of the configuration of the detection circuit 40. In the present embodiment, the detection circuit 40 includes a PGA (programmable gain amplifier) 41, a first synchronous detection circuit 42, a first low-pass filter (first LPF) 43, a first A/D conversion circuit (first ADC) 44, a clip processing section 45, an IIR (infinite impulse response) filter 46, and a DSP (digital signal processor) 47. It is possible to realize the PGA 41, the first synchronous detection circuit 42, the first low-pass filter 43, and the first A/D conversion circuit 44 by using various publicly known analog circuits. It is possible to realize the clip processing section 45, the IIR filter 46, and the DSP 47 by using various publicly known digital circuits. The digital circuits may be realized by using various integrated circuits, such as a CPU or the like, or a programmable gate array or the like.

The PGA 41 is a circuit that amplifies the signal output from the amplification circuit 30. The PGA 41 includes a differential amplification circuit and an AC amplification circuit, performs differential amplification in accordance with the first and the second voltage signals, which constitute the differential signal output from the amplification circuit 30, and further amplifies the obtained signal.

The first synchronous detection circuit 42 is a multiplication circuit that performs synchronous detection by multiplying the signal output from the PGA 41 and the synchronous detection signal SDET output from the comparator 24. Also, the first low-pass filter 43 is a circuit that smooths the signal output from the first synchronous detection circuit 42. With the first synchronous detection circuit 42 and the first low-pass filter 43, a voltage signal corresponding to the angular velocity detected by the sensor element 10 is generated and is output from the first low-pass filter 43.

The first A/D conversion circuit 44 is a circuit that A/D converts the signal output from the first low-pass filter 43 and outputs a signal as a first digital signal Dt1. The DSP 47 performs various kinds of processing in accordance with the first digital signal Dt1 to generate a detection signal to be output to the outside of the physical quantity sensor 1. The various kinds of processing may be publicly known processing and may be various kinds of filtering processing and temperature compensation processing. The filtering processing may be the same processing as the processing performed by the IIR filter 46. The DSP 47 may output the generated detection signal to the outside via an interface not illustrated, or may be output to the controller 70. In this case, the controller 70 may save the detection signal in the register section 80 or the like and output the detection signal to the outside in response to a request from an external device or the like.

When an instruction using a signal clip_flg is given from a clip processing section 55 described later, the clip processing section 45 sets the value of the signal output from the lip processing section 45 as a fixed value. Whereas, when an instruction using the signal clip_flg is not given from the clip processing section 55, the clip processing section 45 sets the input signal to the clip processing section 45 as an output signal without change. That is, the clip processing section 45 is a circuit that limits the output signal to less than or equal to the fixed value. When the output signal is limited by the clip processing section 45, the detection signal output from the IIR filter 46 described later becomes a fixed value.

The IIR filter 46 is a filter having various functions, such as the function of removing signals in a predetermined frequency band or the like. In the present embodiment, the controller 70 determines the filter coefficient of the IIR filter 46 in accordance with the filter coefficient stored in the register section 80. The IIR filter 46 applies a filter having the characteristics determined by the filter coefficient to the input signal to output a detection signal Sr. The IIR filter 46 is used, for example, for removing signals in a frequency band different from that of the angular velocity of the detection target to be detected by the sensor element 10 or the like. The detection signal Sr output from the IIR filter 46 is input to the failure detection circuit 60.

### 1.2 Configuration of Pseudo-Detection Circuit

Next, a detailed description will be given of the configuration of the pseudo-detection circuit 50. FIG. 3 illustrates an example of the configuration of the pseudo-detection circuit 50. In the present embodiment, the pseudo-detection circuit 50 includes a PGA (programmable gain amplifier) 51, a second synchronous detection circuit 52, a second low-pass filter (second LPF) 53, a second A/D conversion circuit (second ADC) 54, a clip processing section 55, and an IIR (infinite impulse response) filter 56. It is possible to realize the PGA 51, the second synchronous detection circuit 52, the second low-pass filter 53, and the second A/D conversion circuit 54 by using various publicly known analog circuits. It is possible to realize the clip processing section 55 and an IIR filter 56 by using various publicly known digital circuits. The digital circuits may be realized by using various integrated circuits, such as a CPU or the like, or a programmable gate array or the like.

The second synchronous detection circuit 52 is a multiplication circuit that performs synchronous detection by multiplying the signal output from the amplification circuit 30 and the synchronous detection signal SDET output from the comparator 24. Also, the second low-pass filter 53 is a circuit that smooths the signal output from the second synchronous detection circuit 52. With the second synchronous detection circuit and the second low-pass filter 53, a voltage signal corresponding to the angular velocity detected by the sensor element 10 is generated and is output from the second low-pass filter 53.

The PGA 51 is a circuit that amplifies the signal output from the second low-pass filter 53. The PGA 51 includes a differential amplification circuit and an AC amplification circuit, performs differential amplification on each signal output from the second low-pass filter 53, and further amplifies the obtained signal. The second A/D conversion circuit 54 is a circuit that A/D converts the signal output from the PGA 51 and outputs the converted signal as a second digital signal Dt2.

When the input signal (absolute value) exceeds a predetermined value, the clip processing section 55 limits the output signal to a fixed value, whereas when the input signal is less than or equal to a predetermined value, the clip processing section 55 sets the input signal as an output signal without change. The predetermined value is a value determined in advance and is a value lower than the maximum value of the input range of the second A/D conversion circuit 54. That is, the clip processing section 55 is a circuit that limits the output signal to less than or equal to a fixed value. When the output signal is limited by the clip processing section 55, the detection signal output from the IIR filter 56 described later becomes a fixed value.

Also, when the input signal (absolute value) exceeds a predetermined value, the clip processing section 55 outputs a signal clip_flg that instructs to start clipping to the clip processing section 45. Accordingly, when a clip processing section 55 described later gives an instruction using the signal clip_flg, the clip processing section 45 sets the output signal output from the clip processing section 45 to a fixed value. Also, when the clip processing section 55 does not give an instruction using the signal clip_flg, the clip processing section 45 sets the input signal to the clip processing section 45 as an output signal without change. In this regard, the clip processing section 55 outputs the signal clip_flg also to a value determination section 64 and controls whether the value determination is enabled or disabled by the signal clip_flg.

The IIR filter 56 is a filter having various functions, such as the function of removing signals in a predetermined frequency band or the like. In the present embodiment, the controller 70 determines the filter coefficient of the IIR filter 56 in accordance with the filter coefficient stored in the register section 80. The IIR filter 56 applies a filter having the characteristics determined by the filter coefficient to the input signal to output a pseudo-detection signal Sp. In the present embodiment, the filter coefficient of the IIR filter 56 is set, for example, to a value for outputting a signal having the same characteristics as those of the IIR filter 46. The pseudo-detection signal Sp output from the IIR filter 56 is input to the failure detection circuit 60.

In the present embodiment, the pseudo-detection circuit 50 includes switches SW1 to SW4. The switch SW1 is disposed between the second low-pass filter 53 and the PGA 51, and the switch SW4 is disposed between the second A/D conversion circuit 54 and the clip processing section 55. The switch SW2 is disposed between the temperature sensor 90 and the PGA 51, and the switch SW3 is disposed between the second A/D conversion circuit 54 and the DSP 47.

The switches SW1 to SW4 are on/off controlled by control signals SEL1 an SEL2 output from the controller 70 as described below. The control signals SEL1 and SEL2 are signals with reverse phases with respect to each other. When the control signal SEL1 is set on, the control signal SEL2 is set off. When the control signal SEL1 is set off, the control signal SEL2 is set on.

The switches SW1 and SW4 are controlled by the control signal SEL1, and the switches SW2 and SW3 are controlled by the control signal SEL2. Accordingly, when the switches SW1 and SW4 are turned on by the control signal SEL1, the switches SW2 and SW3 are turned off by the control signal SEL2. In this state, the pseudo-detection circuit 50 is not electrically coupled to the temperature sensor 90 and the DSP 47, and the pseudo-detection circuit 50 becomes the state of outputting the pseudo-detection signal Sp in accordance with the output signal from the amplification circuit 30.

When the switches SW1 and SW4 are turned off by the control signal SEL1, the switches SW2 and SW3 are turned on by the control signal SEL2. In this state, the output signal of the second low-pass filter 53 of the pseudo-detection circuit 50 is not supplied to the PGA 51, and the output signal of the second A/D convert circuit 54 is not supplied to the clip processing section 55. Accordingly, the pseudo-detection signal Sp is not output. In the state, the temperature sensor 90 is coupled to the PGA 51, and the output signal of the second A/D conversion circuit 54 is input to the DSP 47. Accordingly, the signal detected by the temperature sensor 90 is amplified by the PGA 51, is converted to a digital temperature detection signal by the second A/D conversion circuit 54, and is input to the DSP 47.

In this regard, although the transmission path of the output signal of the temperature sensor 90 is denoted by an arrow, the output signal of the temperature sensor 90 according to the present embodiment is a differential signal, and thus two kinds of the signals are input to the PGA 51. Accordingly, the PGA 51 performs differential amplification on the signal output by the temperature sensor 90 in the same manner as the signal output by the second low-pass filter 53. The second A/D conversion circuit 54 converts the signal after the differential amplification to a digital temperature detection signal, and outputs the digital temperature detection signal to the DSP 47.

As a result, the DSP 47 is able to obtain the temperature detected by the temperature sensor 90. The DSP 47 performs temperature compensation processing on the detection signal generated from the signal output from the sensor element 10 in accordance with the obtained temperature detection signal. That is, the DSP 47 performs predetermined processing in accordance with the first digital signal Dt1 to obtain a detection signal indicating the detection result by the sensor element 10. At this time, the DSP 47 performs correction to offset a characteristic change of the sensor element 10 caused by the temperature.

In the present embodiment, by controlling the switches SW1 to SW4, the controller 70 switches the state to output a pseudo-detection signal Sp from the pseudo-detection circuit 50 and the state to perform temperature compensation processing in accordance with the detection result of the temperature sensor 90. That is, under the control of the controller 70, the second A/D conversion circuit 54 performs the A/D conversion for generating a pseudo-detection signal Sp and the A/D conversion for generating a temperature detection signal in time division. With the configuration described above, it is possible to generate a pseudo-detection signal Sp and the temperature detection signal by using a common circuit, and thus the physical quantity sensor 1 is able to be realized at low cost.

In this regard, in the present embodiment, in order to generate a temperature detection signal from the detection result of the temperature sensor 90, the circuit is configured in the order of inputting the output signal of the PGA 51 to the second A/D conversion circuit 54. However, when the temperature compensation processing in accordance with the temperature detection signal is not performed, or when the temperature compensation processing is performed not by sharing the circuit of the pseudo-detection circuit 50, the order of the circuits is not limited. Accordingly, in this case, the circuit may be configured to perform the processing in the same order of the detection circuit 40, for example, the order of the PGA 51, the second synchronous detection circuit 52, the second low-pass filter 53, and the second A/D conversion circuit 54.

In this regard, in the present embodiment, the second A/D conversion circuit 54 is used not only for generating the pseudo-detection signal Sp but also used for generating the temperature detection signal. The second A/D conversion circuit 54 is therefore configured to have sufficient performance necessary for generating the temperature detection signal. Accordingly, the second A/D conversion circuit 54 may not have sufficient performance necessary for detecting the physical quantity produced by the sensor element 10, and thus may be a circuit simpler than the first A/D conversion circuit 44 used in the detection circuit 40.

Thus, in the present embodiment, the configuration is made by a circuit in which the resolution of the second A/D conversion circuit 54 is lower than the resolution of the first A/D conversion circuit 44. Specifically, the resolution of the first A/D conversion circuit 44 is 16 bits, but the resolution of the second A/D conversion circuit 54 is 10 bits. With the configuration described above, it is possible to realize the physical quantity sensor 1 at low cost compared with the case of configuring the second A/D conversion circuit 54 by using the equivalent circuit to the first A/D conversion circuit 44 used in the detection circuit 40.

Further, in the present embodiment, the second A/D conversion circuit 54 is configured by a circuit simpler than the first A/D conversion circuit 44, and thus the input range of the second A/D conversion circuit 54 is smaller than the input range of the first A/D conversion circuit 44. For example, the configuration is employed such that the input range of the second A/D conversion circuit 54 is 1.2 V, but the input range of the first A/D conversion circuit 44 is 1.8 V. In the case of this configuration, the second A/D conversion circuit 54 converts an analog voltage signal ranging from −1.2 V to 1.2 V to a second digital signal Dt2. On the other hand, the first A/D conversion circuit 44 converts an analog voltage signal ranging from −1.8 V to 1.8 V to a first digital signal Dt1.

In the present embodiment, the PGA 51, the second synchronous detection circuit 52, and the second low-pass filter 53 have the same functions as those of the PGA 41, the first synchronous detection circuit 42, and the first low-pass filter 43, respectively, and their transfer function characteristics are similar. However, the individual circuits do not exactly match each other. The gains of the PGAs 41 and 51 or the like might differ from each other, and thus the function forms (variable order, variables appearing in the denominator and the numerator, the form of addition, subtraction, multiplication, and division to the variables) of the transfer characteristics are identical. On the other hand, the coefficients included in the transfer functions are similar values to each other, but are not exactly the same. Accordingly, in the present embodiment, the value of the signal input to the first A/D conversion circuit 44 in accordance with the signal from the sensor element 10 and the value of the signal input to the second A/D conversion circuit 54 are substantially the same by design, and the change characteristics (rate of change over time or the like) are substantially the same.

In the present embodiment, the failure detection circuit 60 then performs failure determination by determining whether or not the difference between the detection signal Sr generated in accordance with the first digital signal Dt1 output by the first A/D conversion circuit 44 and the pseudo-detection signal Sp generated in accordance with the second digital signal Dt2 output by the second A/D conversion circuit 54 is higher than a threshold value (the details will be described later). Accordingly, even though it is normal, when the value of the detection signal Sr and the value of the pseudo-detection signal Sp are deviated beyond the reference, a determination is made that it is a failure. Such a situation might occur due to the difference of the respective input ranges of the first A/D conversion circuit 44 and the second A/D conversion circuit 54. For example, a situation might occur in which the output signal of the PGA 51 exceeds the input range of the second A/D conversion circuit 54, but the output signal of the first low-pass filter 43 does not exceed the input range of the first A/D conversion circuit 44. In this case, the second digital signal Dt2 output from the second A/D conversion circuit 54 is a saturation value (for example, a digital value corresponding to the input analog voltage 1.2 V), but the first digital signal Dt1 output from the first A/D conversion circuit 44 is an unsaturated value (for example, a digital value corresponding to the input analog voltage 1.5 V).

In this case, the difference between the detection signal Sr and the pseudo-detection signal Sp becomes larger than the threshold value, but this situation is not a failure. Thus, in the present embodiment, when the second digital signal Dt2 output from the second A/D convert circuit 54 having a relatively small input range exceeds a predetermined value, the first digital signal Dt1 and the second digital signal Dt2 are clipped by the clip processing section 45 and the clip processing section 55 respectively, and the determination described above is not performed. That is, when the second digital signal Dt2, which is output from the second A/D conversion circuit 54 and input to the clip processing section 55, exceeds a predetermined value, it is considered that the input signal to the second A/D convert circuit 54 possibly exceeds the input range, and thus the failure determination is disabled.

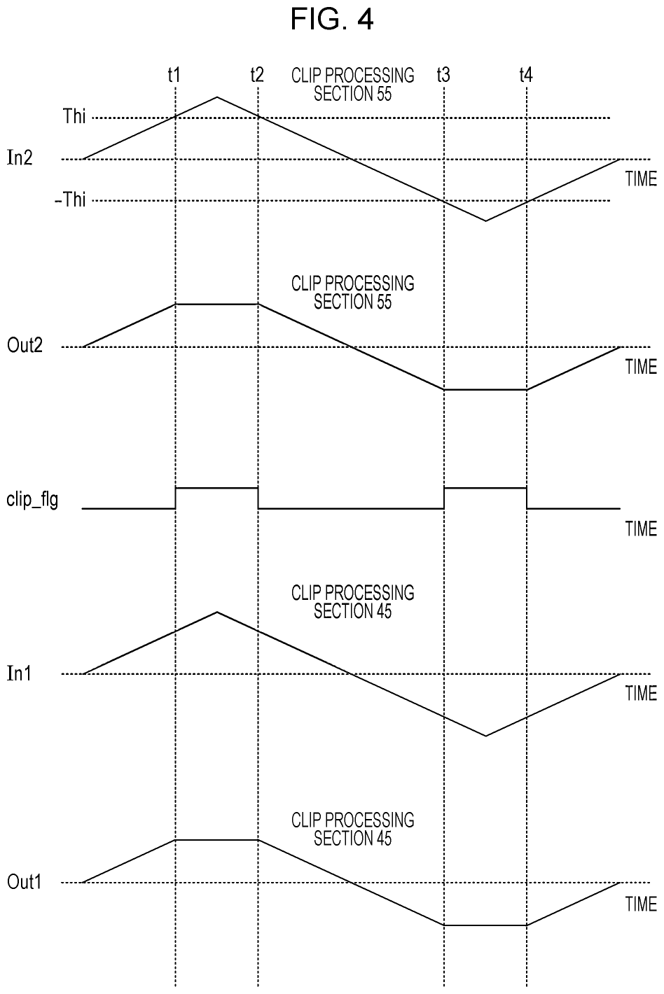

FIG. 4 is a diagram illustrating an input signal In1 and an output signal Out1 of the clip processing section 45, an input signal In2 and an output signal Out2 of the clip processing section 55, and the clip_flg output from the second A/D conversion circuit 54. In FIG. 4, the horizontal axis denotes time, and the vertical axis denotes signal level. As illustrated in FIG. 4, when the value (absolute value) of the input signal In1 to the clip processing section 55 exceeds a predetermined value Thi, the output signal Out2 is clipped and fixed to the predetermined value Thi. In the example illustrated in FIG. 4, during the period from time t1 to t2 and the period from time t3 to t4, the value (absolute value) of the input signal In1 exceeds the predetermined value Thi, and thus the output signal Out2 is clipped.

When clipping is performed by the clip processing section 55, the clip processing section 55 outputs the signal clip_flg instructing the start of clipping to the clip processing section 45. As a result, the input signal In1 to the clip processing section 45, illustrated in FIG. 4, is clipped during the periods of time t1 to t2 and time t3 to t4, and becomes the output signal Out1. The predetermined value for determining whether or not to perform the clip processing is a value lower than the maximum value of the input range of the second A/D conversion circuit 54. Accordingly, when clipping is performed in a case where the second digital signal Dt2 is equal to or higher than the predetermined value, the clipping is performed at least when the input signal to the second A/D conversion circuit 54 exceeds the maximum value of the input range. When the clipping is performed, the failure detection circuit 60 described later is disabled. Accordingly, it is possible to disable the failure detection circuit 60 in the situation in which the input signal to the second A/D conversion circuit 54 exceeds the maximum value of the input range, and the second digital signal Dt2 is not able to reflect the input signal to the second A/D conversion circuit 54. With the configuration described above, when a determination is made in accordance with the difference in the respective output results of the A/D conversion circuits having different input ranges, it is possible to configure so as not to occur an erroneous determination caused by the difference in the input ranges.

On the other hand, when a failure occurs in the detection circuit 40, there are cases in which the second digital signal Dt2 does not exceed the predetermined value, but the first digital signal Dt1 significantly deviates from the second digital signal Dt2. Typically, a failure mode is thought in which the first digital signal Dt1 output from the first A/D conversion circuit 44 is saturated to a maximum positive value or a maximum negative value. In such a case, since the output from the second A/D conversion circuit 54 does not exceed a predetermined value, the clip processing sections 55 and 45 do not perform clipping.

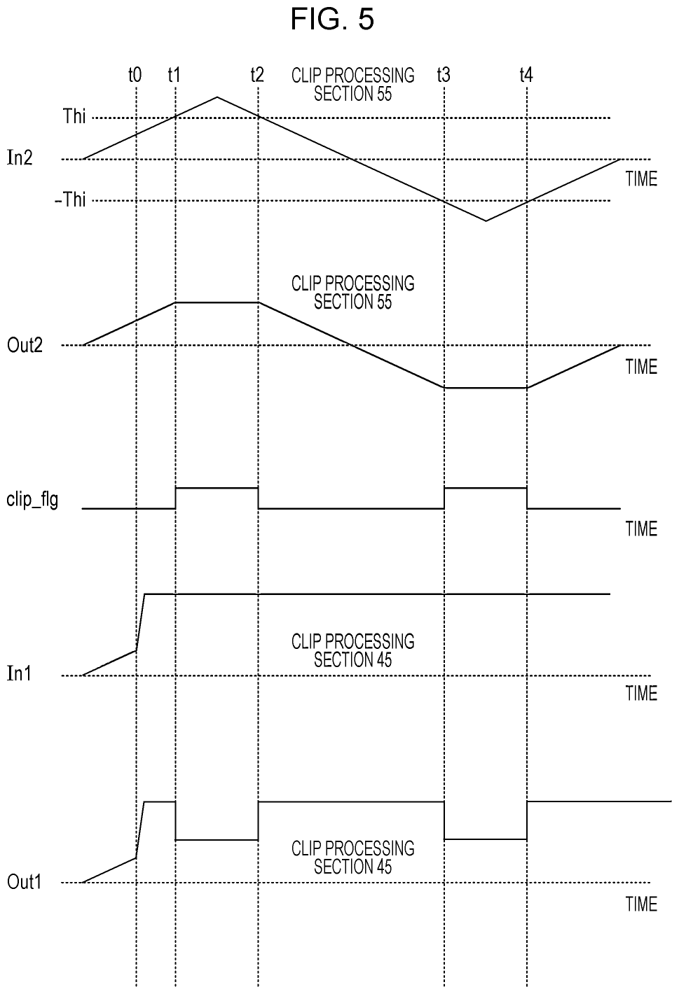

FIG. 5 illustrates an example in which at time to, for example, a failure occurs in the PGA 41, and the first digital signal Dt1 output from the first A/D conversion circuit 44, that is, the input signal In1 to the clip processing section 45 is saturated. In this example, at time to, the second digital signal Dt2 output from the second A/D conversion circuit 54, that is, the input signal In2 to the clip processing section 55 is less than or equal to the predetermined value Thi, and thus the clip processing is not performed. Accordingly, the failure detection circuit 60 is enabled. In this situation, the output from the clip processing section 45 is also saturated, and thus the detection signal Sr output from the detection circuit 40 becomes high. As a result, the difference between the detection signal Sr and the pseudo-detection signal Sp becomes larger than the threshold value, and thus this results in a state enabling the failure detection circuit 60 to detect a failure.

In this regard, in the present embodiment, whether or not to perform clip processing is determined in accordance with the output signal of the second A/D conversion circuit 54. However, the input signal of the second A/D conversion circuit 54 and the output signal thereof have a corresponding relationship, and thus whether or not to perform clip processing may be determined in accordance with the input signal of the second A/D conversion circuit 54.

### 1.3 Configuration of Failure Detection Circuit

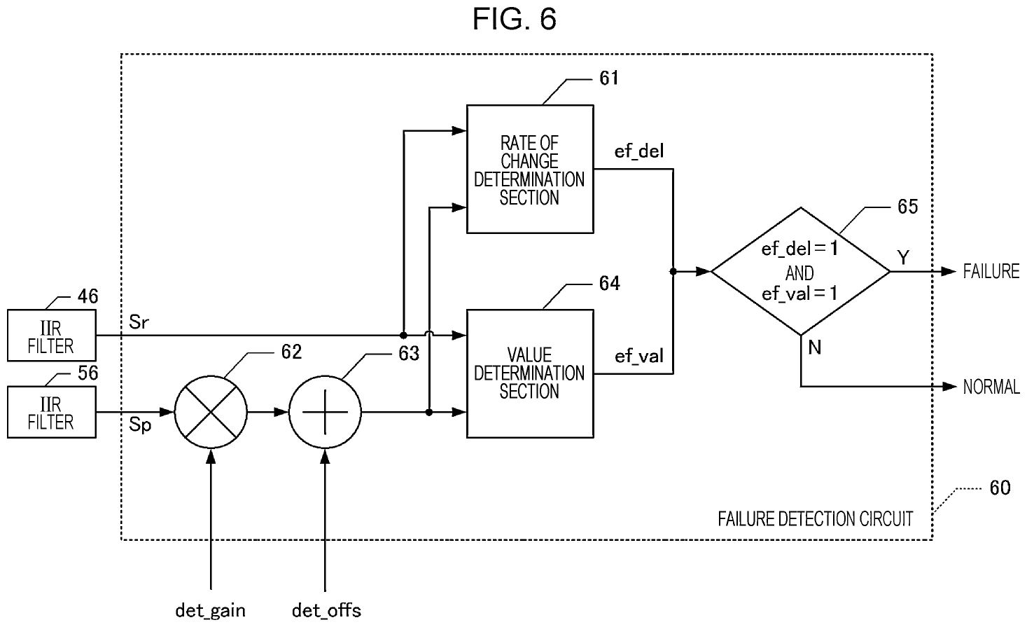

Next, a detailed description will be given of the configuration of the failure detection circuit 60. FIG. 6 is a diagram illustrating the configuration of the failure detection circuit 60. The failure detection circuit 60 is a digital circuit that performs predetermined processing in accordance with the detection signal Sr output from the IIR filter 46 included in the detection circuit 40 and the pseudo-detection signal Sp output from the IIR filter 56 included in the pseudo-detection circuit 50. The digital circuit may be realized by using various integrated circuits, such as a CPU or the like, or may be realized by using a programmable gate array or the like. FIG. 6 is a block diagram illustrating each function of the digital processing.

The failure detection circuit 60 includes a rate of change determination section 61, a multiplication section 62, an addition section 63, the value determination section 64, and a failure determination section 65. The detection signal Sr and the pseudo-detection signal Sp are input to the failure detection circuit 60. In the present embodiment, the multiplication section 62 multiplies the pseudo-detection signal Sp by the gain (det_gain), and the addition section 63 adds the offset (det_offs) to the product of the multiplication. In this regard, the gain (det_gain) and the offset (det_offs) are determined in advance and stored in the register section 80. The controller 70 obtains the gain (det_gain) and the offset (det_offs) and adjusts the multiplication section 62 and the addition section 63 so as to produce the obtained gain (det_gain) and offset (det_offs). The gain (det_gain) and the offset (det_offs) are set such that the difference in the circuit characteristics between the detection circuit 40 and the pseudo-detection circuit 50 and unexpected difference in the design are eliminated, and the values and the characteristics of the detection signal Sr and the pseudo-detection signal Sp become substantially the same.

The detection signal Sr and the pseudo-detection signal Sp corrected by the gain (det_gain) and the offset (det_offs) are input to the rate of change determination section 61. The rate of change determination section 61 calculates a flag ef_del for detecting a failure in accordance with a change in the detection signal Sr and a change in the corrected pseudo-detection signal Sp. The calculation method of the flag ef_del will be described later. The flag ef_del is set off when a change in the detection signal Sr matches a change in the corrected pseudo-detection signal Sp, whereas is set on when they do not match.

The pseudo-detection circuit 50 is a replica of the detection circuit 40. Accordingly, when the detection circuit 40 and the pseudo-detection circuit 50 operate normally, the detection signal Sr and the corrected pseudo-detection signal Sp are supposed to have the same characteristics qualitatively. Accordingly, when the detection circuit 40 and the pseudo-detection circuit 50 operate normally, it is assumed that the detection signal Sr and the pseudo-detection signal Sp have the same change characteristics. Thus, in the present embodiment, when a change in the detection signal Sr and a change in the corrected pseudo-detection signal Sp do not match, the rate of change determination section 61 sets the flag ef_del on, which indicates that there is a possibility of failure.

Also, the detection signal Sr and the corrected pseudo-detection signal Sp are input to the value determination section 64. The value determination section 64 obtains the difference between the detection signal Sr and the corrected pseudo-detection signal Sp, and calculates a flag ef_val for detecting a failure in accordance with the difference. A description will be given later of the calculation method of the flag ef_val. The flag ef_val is a flag which is set off when the difference between the detection signal Sr and the corrected pseudo-detection signal Sp is smaller than or equal to a threshold value, whereas set on when the difference is larger than the threshold value.

In the present embodiment, it is not assumed that the pseudo-detection circuit 50 is malfunctioning, and the pseudo-detection signal Sp is corrected so that the values and the characteristics of the detection signal Sr and the pseudo-detection signal Sp become substantially the same. Accordingly, when the detection circuit 40 is not malfunctioning, it is estimated that the detection signal Sr and the pseudo-detection signal Sp substantially match. That is, when the detection signal Sr and the corrected pseudo-detection signal Sp do not match, the value determination section 64 sets the flag ef_val on, which indicates that there is a possibility of failure.

The failure determination section 65 determines whether or not the detection circuit 40 is malfunctioning in accordance with the flag ef_del set by the rate of change determination section 61 and the flag ef_val set by the value determination section 64. Specifically, when both the flag ef_del and the flag ef_val are on (1), the failure detection circuit 60 determines that the detection circuit 40 is malfunctioning. When at least one of the flag ef_del and the flag ef_val is off (0), the failure detection circuit 60 determines that the detection circuit 40 is normal. In this manner, in the present embodiment, when both the flag ef_del and the flag ef_val, each of which indicates the possibility of a corresponding failure, indicate the possibility of failure, a failure is detected. As a result, compared with the configuration in which a failure is detected by using either one of the flags, it is possible to reduce the possibility of erroneous determination of a failure.

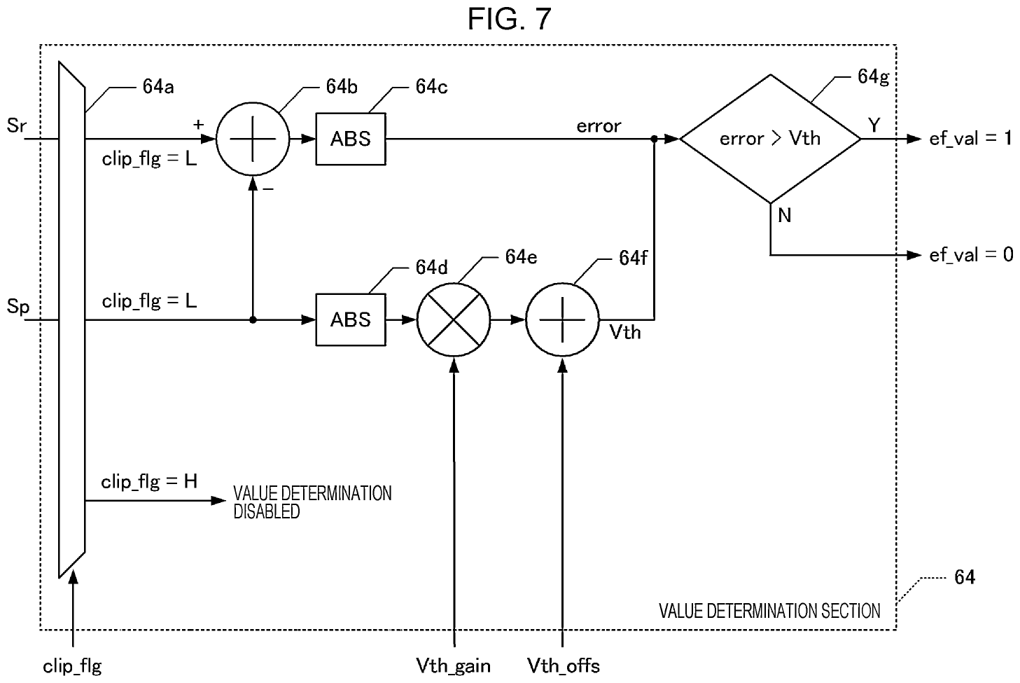

FIG. 7 is a diagram illustrating an example of the configuration of the value determination section 64. In the example of the configuration illustrated in FIG. 7, the value determination section 64 includes a selector 64a, addition sections 64b and 64f, absolute value output sections (ABS) 64c and 64d, a multiplication section 64e, and a comparison section 64g. The selector 64a receives the input of the detection signal Sr and the corrected pseudo-detection signal Sp, and performs the processing to switch the state of outputting the input signal and the state of not outputting the input signal. Specifically, when the signal clip_flg input from the clip processing section 55 is active (the high level in the present embodiment), that is, when the input signal to the clip processing section 55 exceeds the predetermined value, the selector 64a goes to the state of not outputting the input signal to the selector 64a. In this case, the failure detection is not performed by the failure detection circuit 60. As a result, the value determination in the value determination section 64 is disabled.

On the other hand, when the signal clip_flg input from the clip processing section 55 is inactive (the low level in the present embodiment), that is, when the input signal to the clip processing section 55 does not exceed the predetermined value, the selector 64a goes to the state of outputting the input signal to the selector 64a. As a result, the value determination in the value determination section 64 is enabled.

The addition section 64b adds the detection signal Sr output from the selector 64a and the signal produced by multiplying the corrected pseudo-detection signal Sp by a negative sign. That is, the addition section 64b calculates the difference between the detection signal Sr and the corrected pseudo-detection signal Sp. The addition result output from the addition section 64b is input to the absolute value output section 64c, and the absolute value of the addition result is output. That is, an error signal error indicating the difference between the detection signal Sr and the corrected pseudo-detection signal Sp is output.

The corrected pseudo-detection signal Sp output from the selector 64a is also input to the absolute value output section 64d. The absolute value output section 64d outputs the absolute value of the corrected pseudo-detection signal Sp, that is, the signal indicating the magnitude of the signal. The signal is multiplied by the gain (Vth_gain) by the multiplication section 64e, and then the offset (Vth_offs) is added by the addition section 64f. In this regard, the gain (Vth_gain) and the offset (Vth_offs) are determined in advance and stored in the register section 80. The controller 70 obtains the gain (Vth_gain) and the offset (Vth_offs), and adjusts the multiplication section 62 and the addition section 63 so as to produce the obtained gain (Vth_gain) and offset (Vth_offs).

The value output from the addition section 64f becomes a threshold value Vth to be compared with the error signal error. The threshold value Vth is a value for determining that the error signal error is substantially 0, that is, there is no difference between the detection signal Sr and the corrected pseudo-detection signal Sp. Even though the detection signal Sr and the corrected pseudo-detection signal Sp have substantially the same value, the difference does not necessarily become 0 due to an error of the circuit element or the like, and thus the threshold value Vth is set as a value within the range in which the difference is considered 0.

Further, the larger the value of each signal, the wider the range in which the difference between the detection signal Sr and the corrected pseudo-detection signal Sp is regarded as substantially 0. This is because the larger the value of each signal, the larger the noise. Thus, in the present embodiment, the threshold value is changed in accordance with the value of the signal output from the sensor element, that is, the value of the pseudo-detection signal Sp.

In the present embodiment, the threshold value Vth is determined by a linear expression with the pseudo-detection signal Sp as a variable. Specifically, the threshold value Vth is obtained by (the absolute value of the pseudo-detection signal Sp)×(Vth_gain)+(Vth_offs). With this configuration, it is possible to set by using simple processing such that the larger the value of the pseudo-detection signal Sp, the higher the threshold value. In this regard, the configuration is an example, and the configuration in which the threshold value Vth is determined in accordance with an expression other than a linear expression may be employed.

The comparison section 64g compares the error signal error and the threshold value Vth. When the error signal error is higher than the threshold value Vth, the comparison section 64g considers that the value of the detection signal Sr does not match the value of the corrected pseudo-detection signal Sp, and sets the flag ef_val on. When it is not determined that the error signal error is higher than the threshold value Vth, the comparison section 64g sets the flag ef_val off. The flag set by the comparison section 64g is input to the failure determination section 65.

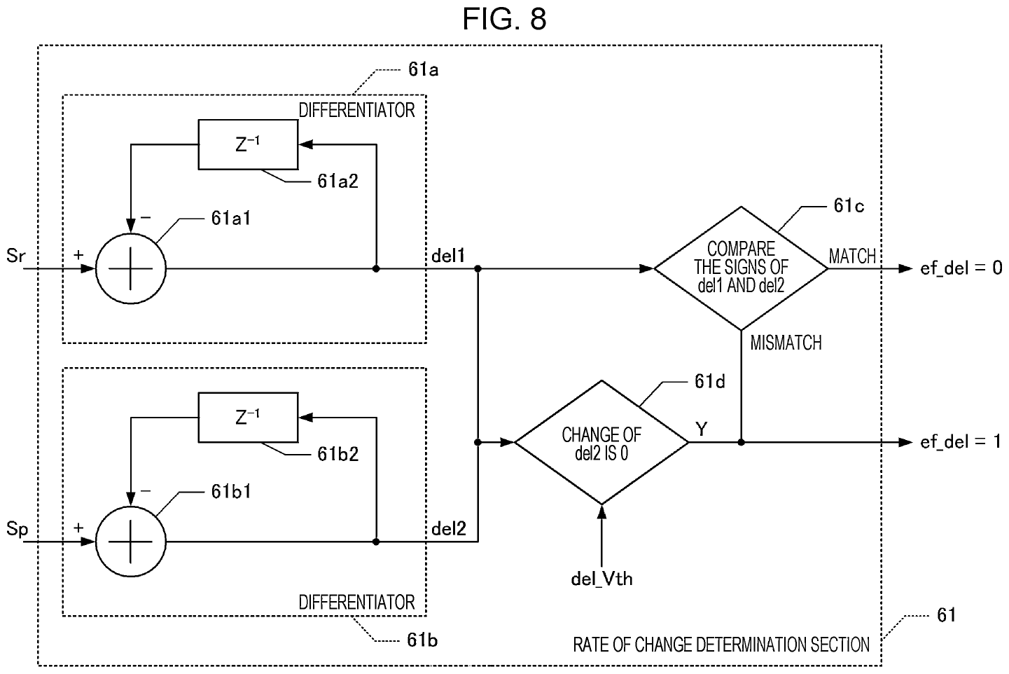

FIG. 8 is a diagram illustrating an example of the rate of change determination section 61. In the example illustrated in FIG. 8, the change of rate determination section 61 includes differentiators 61a and 61b, a sign comparison section 61c, and a change determination section 61d. The differentiator 61a includes an adder 61a1 and a delay section 61a2. The differentiator 61a receives the input of the detection signal Sr. In the differentiator 61a, the adder 61a1 receives the input of the detection signal Sr, and a signal produced by delaying the output of the adder 61a1 by the delay section 61a2 and then adding a negative sign. As a result, a signal produced by differentiating the detection signal Sr with time, that is, a signal del1 indicating the change rate of the detection signal Sr is output.

The differentiator 61b includes an adder 61b1 and a delay section 61b2. The configuration thereof is the same as that of the differentiator 61a. The differentiator 61b receives the input of the pseudo-detection signal Sp, and a signal produced by differentiating the pseudo-detection signal Sp with time, that is, a signal del2 indicating the change rate of the pseudo-detection signal Sp is output.

The signal del1 and the signal del2 are input to the sign comparison section 61c. The sign comparison section 61c compares the respective signs of the signal del1 and the signal del2. That is, the sign comparison section 61c determines whether the respective signs of the signal del1 and the signal del2 are positive or negative, and whether or not they match. When the respective signs of the signal del1 and the signal del2 do not match, the sign comparison section 61c sets the flag ef_del on. When the respective signs of the signal del1 and the signal del2 match, the sign comparison section 61c sets the flag ef_del off. The flag set by the sign comparison section 61c is input to the failure determination section 65.

When the respective signs of the signal del1 and the signal del2 do not match, the changing trends of the detection signal Sr and the corrected pseudo-detection signal Sp are opposite, and thus it is thought that the respective characteristics of the detection signal Sr and the corrected pseudo-detection signal Sp are different. Thus, in the present embodiment, when the respective signs of signal del1 and signal del2 do not match, there is a possibility of failure, and thus the flag ef_val is set on.

The failure determination section 65 illustrated in FIG. 6 determines to be a failure when both the flag ef_del set in accordance with the difference of the values and the flag ef_val set in accordance with the change rate are on (1). On the other hand, the failure determination section 65 determines to be normal when at least one of the flag ef_del and the flag ef_val is off (0). That is, when the difference between the value of the detection signal Sr and the value of the corrected pseudo-detection signal Sp is larger than a threshold value, and the sign of change in the detection signal Sr differs from the sign of change in the corrected pseudo-detection signal Sp, the failure determination section 65 determines to be a failure.

When the difference between the value of the detection signal Sr and the value of the corrected pseudo-detection signal Sp is larger than the threshold value, the value of the detection signal Sr and the value of the corrected pseudo-detection signal Sp are not substantially the same, and thus there is a possibility of failure. Further, when the sign of change in the detection signal Sr differs from the sign of change in the corrected pseudo-detection signal Sp, the change characteristics of the detection signal Sr differs from the change characteristics of the corrected pseudo-detection signal Sp, and thus there is a possibility of failure. In the present embodiment, when the two conditions are met for determining that there is a possibility of failure, it is determined to be a failure. As a result, compared with the configuration in which a failure is determined by using only one condition, it is possible to reduce the possibility of making an erroneous determination.

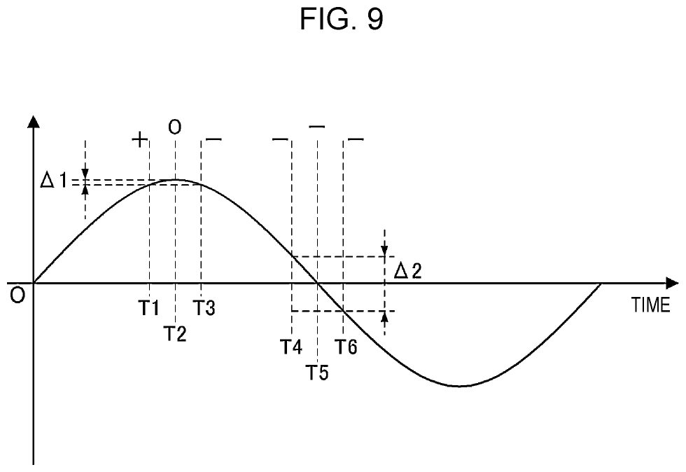

In this regard, in the present embodiment, it is configured not to consider the sign of a signal change in the state in which the determination accuracy in the sign of the signal change is relatively low, and the determination accuracy in the value difference is relatively high. For example, a description will be given by taking as an example the case in which the detection signal Sr and the pseudo-detection signal Sp have the shape such as a sine wave illustrated in FIG. 9. In such a signal, the sign of the signal changes as +, 0, and − in the vicinity of the maximum amplitude value. FIG. 9 illustrates an example in which the signs are +, 0, and − at time T1, T2, and T3 respectively.

On the other hand, when the phase changes 90° from the vicinity of the maximum amplitude value, and the signal reaches in the vicinity of the 0 cross point of amplitude, the signal is monotonically decreasing, and the sign does not change for a while. FIG. 9 illustrates that the sign is − in the vicinity of 0 cross point at time T4, T5, and T6. In the period of time T1 to T3, which is the vicinity of the maximum amplitude value, the signal value change 41 is very small, however, in the period of time T4 to T6, which is the vicinity of 0 cross point of amplitude, the signal value change 42 is relatively large. In this manner, in the vicinity of the maximum amplitude value, the sign fluctuates greatly by a small change of the signal. However, in the phase area different from the phase in the vicinity of the maximum amplitude value, the sign is difficult to change even though the signal changes slightly.

Accordingly, in the vicinity of the maximum amplitude value, the failure detection accuracy in accordance with the change of the signal sign becomes relatively low. In particular, the higher the signal frequency, the lower the failure detection accuracy tends to be. On the other hand, when both the detection signal Sr and the corrected pseudo-detection signal Sp are in the vicinity of the maximum amplitude value, in the case of a normal signal, the difference in the signal values is small, and the possibility in which the difference exceeds the threshold value is low. Accordingly, in the vicinity of the maximum amplitude value, when a determination is made by not using the sign of the signal change, but in accordance with the difference of value, the failure detection accuracy is difficult to become low. Such a situation is not limited to a sine wave, and the same for any signal.

Thus, in the rate of change determination section 61, the signal del2 is input to the change determination section 61d. The change determination section 61d determines whether or not a change in the signal del2 is substantially 0. In the present embodiment, a determination is made whether or not a change in the signal del2 is substantially 0 in accordance with the second threshold value del_Vth. That is, the second threshold value del_Vth indicates the value by which a change in the signal del2 is regarded as 0 and is set in advance. In the present embodiment, the second threshold value del_Vth is a predetermined fixed value, but may be variable in accordance with the value of the signal del2 or the like.

When the value of a change in the signal del2 is smaller than or equal to the second threshold value del_Vth, a change in the signal del2 is regarded as substantially 0. When a change in the signal del2 is substantially 0, the change determination section 61d sets the flag ef_del on. In this case, the determination by the sign comparison section 61c is not reflected on the flag. In the present embodiment, when both the flag ef_del and the flag ef_val are on (1), the failure determination section 65 determines a failure. Accordingly, when the flag ef_del is set on, without the determination by the sign comparison section 61c, a failure is determined in accordance with whether or not the flag ef_val is on. With the configuration described above, when a change in the value of the corrected pseudo-detection signal Sp is less than or equal to the second threshold value del_Vth, a failure is detected in accordance with the result of the comparison between the value of the detection signal Sr and the value of the pseudo-detection signal Sp without a change in the detection signal Sr and the change in the pseudo-detection signal Sp. With the configuration described above, under the condition that the failure detection accuracy might become low, a determination by the change of the signal sign is not performed. Accordingly, it is possible to prevent the failure detection accuracy from decreasing.

### 2. Other Embodiments and the Like

The embodiment described above is an example for carrying out the present disclosure, and it is possible to employ various other embodiments. For example, in the embodiment described above, when the input signal to the clip processing section 55 exceeds a predetermined value, as a state in which the input signal to the selector 64a is not output from the selector 64a, the failure detection is disabled. However, when the input signal to the clip processing section 55 exceeds a predetermined value, the input signal to the selector 64a may be output from the selector 64a. In this case, the detection signal Sr generated in accordance with the clipped signal and the pseudo-detection signal Sp are output from the selector 64a, but these values are set as fixed values by clipping. Accordingly, when these fixed values are set to be the same value, a change in the pseudo-detection signal Sp is 0, and there will be no difference between the value of the detection signal Sr and the value of the pseudo-detection signal Sp, and thus it becomes normal. Accordingly, it goes to a state in which a failure is not detected, that is, the failure detection is disabled.

Further, when the value determination is disabled by the selector 64a, the data produced immediately after switching by the selector 64a may not be used for the value determination.

The detection circuit is a circuit including the first A/D conversion circuit that performs A/D conversion on the signal output from the sensor element to output a first digital signal, and generating a detection signal in accordance with the first digital signal. That is, the detection circuit only needs to perform analog/digital conversion on the detection result produced by the sensor element to generate a digital detection signal. Such a configuration is not limited to the embodiment described above, and various alternative methods may be used, and various functions may be omitted or added. For example, the number of bits of the first A/D conversion circuit is not limited to the configuration described above, or the order of the circuits for detection and the PGA may be opposite. Also, a down-sampling filter may be applied on the output of the first A/D conversion circuit, and gain adjustment or offset adjustment may be performed. Further, various kinds of processing may be performed on the signal before being input to the first A/D conversion circuit, for example, gain adjustment, offset adjustment, or the like may be performed.

The sensor element only needs to detect various kinds of detection target, such as a physical quantity or the like. For detecting a physical quantity, the detection target is not limited to the angular velocity described above, and may be, for example, acceleration, angular acceleration, speed, distance, temperature, pressure, sound pressure, magnetic quantity, or the like. Of course, two or more of the physical quantities may be the detection targets. Also, the configurations of the detection circuit 40 and the pseudo-detection circuit 50 may be changed in accordance with the physical quantity of the detection target. For example, when a sensor element outputting a signal that does not require differential amplification is used, a configuration not including a differential amplification circuit may be employed. In this regard, “the signal output from the sensor element” may include a signal produced by performing various kinds of processing on the output signal from the sensor element.

The detection signal is a signal indicating a detection target of the sensor element and only needs to be generated in accordance with the first digital signal. That is, the first digital signal is a signal indicating the result of the signal obtained by the sensor element, and the detection signal only needs to be expressed in a format that enables the detection result by the sensor element to be used by the other device. The first digital signal and the detection signal may be the same signal.

The pseudo-detection circuit only needs to include the second A/D conversion circuit that performs the A/D conversion on the signal output from the sensor element to output the second digital signal to generate the pseudo-detection signal in accordance with the second digital signal. That is, the pseudo-detection circuit only needs to perform analog/digital conversion on the detection result by the sensor element to generate a digital pseudo-detection signal. Such a configuration is not limited to the embodiment described above, and various alternative methods may be used, various functions may be omitted or added. For example, the number of bits of the second A/D conversion circuit is not limited to those of the configuration described above, and the order of the detection circuit and the PGA may be opposite. Also, a down-sampling filter may be applied to the output of the second A/D conversion circuit, and gain adjustment and offset adjustment may be performed. Further, various kinds of processing, for example, gain adjustment, offset adjustment, and the like may be performed on the signal before the signal is input to the second A/D conversion circuit.

The pseudo-detection signal is a signal indicating the detection target of the sensor element and is generated in accordance with the second digital signal, and is reproduced from the detection signal in a pseudo-manner. The pseudo-detection signal is a signal that reproduces the detection signal in a pseudo-manner, and thus the pseudo-detection signal may not be used for detecting the physical quantity or the like obtained by sensor element. Also, the circuit for reproducing the detection signal in a pseudo-manner to generate the pseudo-detection signal may be the same circuit as the detection circuit, a circuit having at least a part same as that of the detection circuit, or a circuit having the same function but different specification. Here, a circuit having the same function means having a transfer function with the same characteristics but different coefficient and constant. In any case, the pseudo-detection circuit only needs to be designed to generate the difference between the pseudo-detection signal and the detection signal by reproducing the behavior of the detection signal by using the pseudo-detection signal when a failure occurs in the detection circuit. The second digital signal and the pseudo-detection signal may be the same signal.

The failure detection circuit only needs to perform failure detection of the detection circuit in accordance with the result of the comparison between the value of the detection signal and the value of the pseudo-detection signal. That is, the failure detection circuit only needs to compare the value of the detection signal generated by the detection circuit and the value of the pseudo-detection signal generated by the pseudo-detection circuit imitating the detection circuit, and to identify whether or not the detection circuit is normal in accordance with the difference. The difference between the value of the detection signal and the value of the pseudo-detection signal may be evaluated by various methods. For example, the failure detection is performed in accordance with the difference between the value of the detection signal described above and the value of the pseudo-detection signal, and the changes thereof. However, failure detection may be performed in accordance with either one of the difference and the change. Also, the other element may be added to the evaluation element of the difference. Also, various processing other than clipping may be performed for identifying the value of the detection signal and the value of the pseudo-detection signal.

The embodiments described above give an example, and the present disclosure is not limited to these embodiments. The present disclosure includes a component having substantially the same component as described in the embodiments (for example, a component having the same function, a method, and a result or a component having the same purpose and advantages). Also, the present disclosure includes a component described in the embodiments, of which nonessential part is replaced. Also, the present disclosure includes a component configured to have the same operational advantages or accomplish the same purposes as those of the component described in the embodiments. Also, the present disclosure includes a component produced by adding a publicly known technique to the component described in the embodiments.

What is claimed is:

1. A circuit device comprising:
a detection circuit configured to include a first A/D conversion circuit that A/D converts a signal output from a sensor element to output a first digital signal and generate a detection signal in accordance with the first digital signal;
a pseudo-detection circuit configured to include a second A/D conversion circuit that A/D converts a signal output from the sensor element to output a second digital signal and generate a pseudo-detection signal in accordance with the second digital signal; and
a failure detection circuit configured to detect a failure of the detection circuit in accordance with a comparison result produced by comparing a value of the detection signal and a value of the pseudo-detection signal.

2. The circuit device according to claim 1, wherein
the failure detection circuit detects the failure in accordance with whether or not the difference between the value of the detection signal and the value of the pseudo-detection signal is less than or equal to a threshold value, and the threshold value changes in accordance with the signal output from the sensor element.

3. The circuit device according to claim 2, wherein
the threshold value is determined by a linear expression with the pseudo-detection signal as a variable.

4. The circuit device according to claim 1, further comprising a drive circuit that generates a drive signal driving the sensor element, wherein
the detection circuit includes a first synchronous detection circuit that synchronously detects the signal output from the sensor element by a synchronous detection signal in accordance with the drive signal and a first low-pass filter that smooths a signal output from the first synchronous detection circuit,
the first A/D conversion circuit A/D converts a signal output from the first low-pass filter,
the pseudo-detection circuit includes a second synchronous detection circuit that synchronously detects the signal output from the sensor element by the synchronous detection signal and a second low-pass filter that smooths a signal output from the second synchronous detection circuit, and
the second A/D conversion circuit A/D converts a signal output from the second low-pass filter.

5. The circuit device according to claim 1, wherein
resolution of the second A/D conversion circuit is lower than resolution of the first A/D conversion circuit.

6. The circuit device according to claim 1, wherein
the detection circuit performs temperature compensation processing on the detection signal in accordance with a temperature detection signal, and
the second A/D conversion circuit performs A/D conversion for generating the pseudo-detection signal and A/D conversion for generating the temperature detection signal by time division.

7. The circuit device according to claim 1, wherein
an input range of the second A/D conversion circuit is smaller than an input range of the first A/D conversion circuit, and
when a value of the output signal from the second A/D conversion circuit is larger than a predetermined value, the detection signal and the pseudo-detection signal become respective fixed values.

8. The circuit device according to claim 1, wherein
the failure detection circuit detects a failure in accordance with the comparison result, a change in the detection signal, and a change in the pseudo-detection signal.

9. The circuit device according to claim 8, wherein
when the comparison result indicates that a difference between the value of the detection signal and the value of the pseudo-detection signal is larger than a threshold value, and a sign of the change in the detection signal differs from a sign of the change in the pseudo-detection signal, the failure detection circuit determines a failure; and
when a change in the pseudo-detection signal is less than or equal to a second threshold value, the failure detection circuit detects a failure in accordance with the comparison result regardless of a change in the detection signal and a change in the pseudo-detection signal.

10. A physical quantity sensor comprising:
a sensor element;
a detection circuit configured to include a first A/D conversion circuit that A/D converts a signal output from the sensor element to output a first digital signal and generate a detection signal in accordance with the first digital signal;
a pseudo-detection circuit configured to include a second A/D conversion circuit that A/D converts a signal output from the sensor element to output a second digital signal and generate a pseudo-detection signal in accordance with the second digital signal; and
a failure detection circuit configured to detect a failure of the detection circuit in accordance with a comparison result produced by comparing a value of the detection signal and a value of the pseudo-detection signal.

11. The physical quantity sensor according to the claim 10, further comprising
a drive circuit that drives the sensor element, wherein
the signal output from the sensor element is a signal corresponding to an angular velocity detected by the sensor element.
